(19) United States
(12) Patent Application Publication
(10) Pub. No.: US 2006/0209514 A1
(43) Pub. Date: Sep. 21, 2006

(54) Semiconductor device and manufacturing method therefor

(75) Inventor: Tatsuya Katoh, Kasaoka-shi (JP)

Correspondence Address: HARNESS, DICKEY & PIERCE, P.L.C., P.O. BOX 8910, RESTON, VA, 20195, US

(73) Assignee: Sharp Kabushiki Kaisha

(21) Appl. No.: 11/377,861

(22) Filed: Mar. 17, 2006

(30) Foreign Application Priority Data
Mar. 18, 2005 (JP) 2005-079167

(51) Int. Cl. H05K 7/20

(52) U.S. Cl. 361/705; 361/688

(57) ABSTRACT

The semiconductor device of the invention has a heat spreader 9 mounted on a semiconductor element 5. The area of one surface of the heat spreader 9 closer to the semiconductor element 5 is generally equal to the area of one surface of the semiconductor element 5 closer to the heat spreader 9. With this structure, manufacturing cost of the semiconductor device can be reduced and moreover its reliability can be enhanced.

### CROSS-REFERENCE TO RELATED APPLICATIONS

The present non-provisional application claims priority based on JP 2005-079167 applied for patent in Japan on Mar. 18, 2005 under U.S. Code, Volume 35, Chapter 119(a). The disclosure of the application is fully incorporated herein by reference.

### BACKGROUND OF THE INVENTION

The present invention relates to a semiconductor device and a manufacturing method therefor.

Conventionally, there has been provided a semiconductor device which adopts TCP (Tape Carrier Package) fabricated by TAB (Tape Automated Bonding) technique (see, for example, JP H5-160194 A). In this semiconductor device, a heat spreader is provided on a rear face of a semiconductor element (the rear face being opposite to the front face of the semiconductor element on which bumps are formed) for efficient radiation of heat generated by operations of the semiconductor element.

A COF (Chip On Film) semiconductor device equipped with a heat spreader, which is one of the conventional semiconductor devices, is described below.

The COF semiconductor device equipped with a heat spreader, as shown in FIG. 7, includes a flexible tape board 101, and a semiconductor element 105 mounted on the flexible tape board 101.

The flexible tape board 101 has a base film 102, interconnection lines 103 formed on the base film 102, and resist 104 formed on the interconnection lines 103. This resist 104 is formed so as not to cover part of the interconnection lines 103. Also, an underfill resin 107 is filled between the flexible tape board 101 and the semiconductor element 105.

On a front face of the semiconductor element 105, bump electrodes (bumps) 106 made of gold or the like are formed while a heat spreader 109 is mounted on the rear face of the semiconductor element 105 via adhesive 108.

FIG. 8 shows an assembly flowchart of the COF semiconductor device with the heat spreader.

In the assembly method of the COF semiconductor device with the heat spreader, first, a wafer with the bump electrodes 106 formed thereon is subjected to dicing, by which a semiconductor element 105 having the bump electrodes 106 is obtained (step S101).

Next, the interconnection lines 103 made of copper are patterned by etching on the base film 102 formed of long tape, and the interconnection lines 103 are tin- or gold-plated, by which a flexible tape board 101 is formed.

Next, the semiconductor element 105 with the gold or other bump electrodes 106 formed thereon is bonded to the flexible tape board 101 by the COF method (step S102). The process of bonding the semiconductor element 105 to the flexible tape board 101 is referred to as ILB (Inner Lead Bonding). In addition, for the flexible tape board 101, the surface except portions where the ILB is provided is protected by the resist 104.

Next, the underfill resin 107 serving as a protective material is filled between the semiconductor element 105 and the flexible tape board 101, and thereafter subjected to curing so that the underfill resin 107 is cured (step S103).

Next, on the rear face of the semiconductor element 105, a chip-like heat spreader 109 is mounted via adhesive 108 such as solder or resin based Ag paste (step S104).

Finally, an electrical inspection and an appearance inspection are performed, where the COF semiconductor device with the heat spreader is completed (steps S105-S107).

In this connection, when the semiconductor element 105 bears occurrence of heat generation due to electrical operation of the COF semiconductor device with the heat spreader, the radiation path of the heat of the semiconductor element 105 is as shown in (1) and (2) below:

(1) semiconductor element→bump electrodes→underfill resin→flexible board→atmospheric air; and

(2) semiconductor element→heat spreader→atmospheric air.

Without the heat spreader 109 mounted on the semiconductor element 105, the heat on the rear face side of the semiconductor element 105 would be radiated directly into the atmospheric air. However, the thermal conductivity of dry air is as quite low as 0.0241 W/m·K. As a result of this, the heat on the rear face side of the semiconductor element 105 would not be radiated enough, so that the semiconductor element 105 would be incapable of mounting thereon CCLs (Current Mode Logics) or TTLs (Transistor Transistor Logics), which are elements of high power consumption, and besides could not fulfill enough electrical capability.

In contrast to this, with the heat spreader 109 mounted on the semiconductor element 105, it becomes possible to mount CCLs or TTLs on the semiconductor element 105, and moreover electrical capability of the semiconductor element can be developed enough.

However, for the conventional COF semiconductor device with the heat spreader described above, which structurally involves the process of bonding the already piece-individualized heat spreader 109 to the rear face of the semiconductor element, its manufacturing process including the handling of the heat spreader 109 would be quite troublesome. As a consequence, the conventional COF semiconductor device with the heat spreader has issues of high manufacturing cost and low reliability.

### SUMMARY OF THE INVENTION

Accordingly, an object of the present invention is to provide a semiconductor device, as well as a manufacturing method therefor, which is capable of reducing the manufacturing cost and besides enhancing the reliability.

In order to achieve the above object, there is provided a semiconductor device comprising:

a semiconductor element; and a heat spreader mounted on the semiconductor element, wherein

an area of a surface of the heat spreader on one side closer to the semiconductor element is generally equal to an area of a surface of the semiconductor element on one side closer to the heat spreader.

In this semiconductor device, since the area of one surface of the heat spreader closer to the semiconductor element is generally equal to the area of one surface of the semiconductor element closer to the heat spreader, the semiconductor element having the heat spreader mounted thereon can be obtained by bonding the material of the heat spreader to the material of the semiconductor element and thereafter dividing the material of the semiconductor element together with the material of the heat spreader into a plurality of divisions. Accordingly, there is no need for the step of bonding the chip-like heat spreader to the chip-like semiconductor element as would be involved in the prior art example of FIGS. 7 and 8. Thus, the manufacturing process for the semiconductor device can be simplified. As a consequence, the manufacturing cost for the semiconductor device can be reduced and besides the reliability of the semiconductor device can be enhanced.

In one embodiment of the invention, the semiconductor element and the heat spreader are changeable in thickness independently of each other.

In this case, since the semiconductor element and the heat spreader are changeable in thickness independently of each other, it becomes possible to respond to various design changes.

In one embodiment of the invention, the heat spreader is made of metal.

In this case, since the heat spreader is made of metal, heat of the semiconductor element can be dissipated with high efficiency.

In one embodiment of the invention, the heat spreader is bonded to the semiconductor element with a die bond sheet.

In this case, since the heat spreader is bonded to the semiconductor element with a die bond sheet, differences in contraction coefficient between the heat spreader and the semiconductor element can be absorbed by the die bond sheet. Therefore, the heat spreader and the semiconductor element can be prevented from occurrence of warps.

In one embodiment of the invention, the heat spreader is bonded to the semiconductor element with a heat-sinking silicon resin.

In this case, since the heat spreader is bonded to the semiconductor element with a heat-sinking silicon resin, differences in contraction coefficient between the heat spreader and the semiconductor element can be absorbed by the heat-sinking silicon resin. Therefore, the heat spreader and the semiconductor element can be prevented from occurrence of warps.

In one embodiment of the invention, the heat spreader is a die pad portion of a lead frame.

Also, there is provided, a method for manufacturing a semiconductor device comprising the steps of:

bonding a heat sink plate to a wafer; and

subjecting the wafer together with the heat sink plate to dicing to form a semiconductor element formed of part of the wafer and to form a heat spreader formed of part of the heat sink plate.

In this manufacturing method for a semiconductor device, after a heat sink plate is bonded to a wafer including the semiconductor element, the wafer together with the heat sink plate is subjected to dicing. By this step, a semiconductor element is formed of part of the wafer and moreover a heat spreader formed of part of the heat sink plate. Accordingly, there is no need for the step of bonding the chip-like heat spreader to the chip-like semiconductor element as would be involved in the prior art example of FIGS. 7 and 8. Thus, the manufacturing process for the semiconductor device can be simplified. As a consequence, the manufacturing cost for the semiconductor device can be reduced and besides the reliability of the semiconductor device can be enhanced.

Also, the step of making the semiconductor element in the wafer may be carried out either before the step of bonding the heat sink plate to the wafer or after the step of bonding the heat sink plate to the wafer.

Also, there is provided, a semiconductor device comprising:

a tape board having an interconnection pattern; a semiconductor element which is mounted on the tape board so that one face of the semiconductor element faces the tape board; and a heat spreader mounted on the other face of the semiconductor element, wherein

the heat spreader is a die pad portion of a lead frame.

In this semiconductor device, since the heat spreader is a die pad portion of a lead frame, the semiconductor element having the heat spreader mounted thereon can be formed by using the step for conventional mold packages. Accordingly, there is no need for the step of bonding the chip-like heat spreader to the chip-like semiconductor element as would be involved in the prior art example of FIGS. 7 and 8. Thus, the manufacturing process for the semiconductor device can be simplified. As a consequence, the manufacturing cost for the semiconductor device can be reduced and besides the reliability of the semiconductor device can be enhanced.

In one embodiment of the invention, the heat spreader is electrically connected to the interconnection pattern via a lead portion.

In this case, since the interconnection pattern and the heat spreader are electrically connected to each other by the lead portion, electrical characteristics of the semiconductor element such as anti-noise characteristics can be improved.

Also, there is provided a method for manufacturing a semiconductor device comprising the steps of:

die-bonding a semiconductor element to a die pad portion of a lead frame, the lead frame having the die pad portion and a frame portion surrounding the die pad portion with one face of the semiconductor element opposed to the die pad portion;

separating the die pad portion together with the semiconductor element from the frame portion; and

mounting the semiconductor element onto the tape board with the other face of the semiconductor element opposed to the tape board.

In this manufacturing method for the semiconductor device of the above construction, the semiconductor element is die-bonded to the die pad portion of the lead frame with one face of the semiconductor element opposed to the die pad portion of the lead frame, and thereafter the die pad portion together with the semiconductor element is separated from the frame portion. With the other face of the semiconductor element opposed to the tape board, the semiconductor element is mounted on the tape board. As a result of this, the die pad portion functions as a heat spreader of the semiconductor element. Accordingly, there is no need for the step of bonding the chip-like heat spreader to the chip-like semiconductor element as would be involved in the prior art example of FIGS. 7 and 8. Thus, the manufacturing process for the semiconductor device can be simplified. As a consequence, the manufacturing cost for the semiconductor device can be reduced and besides the reliability of the semiconductor device can be enhanced.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a schematic sectional view of a COF semiconductor device with a heat spreader according to a first embodiment of the invention;

FIG. 2A is an assembly flowchart of the COF semiconductor device with the heat spreader of the first embodiment;

FIG. 2B is an assembly process view of the COF semiconductor device with the heat spreader of the first embodiment;

FIG. 2C is an assembly process view of the COF semiconductor device with the heat spreader of the first embodiment;

FIG. 2D is an assembly process view of the COF semiconductor device with the heat spreader of the first embodiment;

FIG. 3 is a schematic sectional view of a modification example of the COF semiconductor device with the heat spreader of the first embodiment;

FIG. 4 is a schematic sectional view of a COF semiconductor device with a heat spreader according to a second embodiment of the invention;

FIG. 5 is an assembly flowchart of the COF semiconductor device with the heat spreader of the second embodiment;

FIG. 6 is a schematic plan view of a lead frame to be used in the manufacture of the COF semiconductor device with the heat spreader of the second embodiment;

FIG. 7 is a schematic sectional view of a conventional COF semiconductor device with an heat spreader;

FIG. 8 is an assembly flowchart of the conventional COF semiconductor device with the heat spreader.

### DETAILED DESCRIPTION OF THE PREFERRED EMBODIMENTS

Hereinbelow, the semiconductor device of the present invention will be described in detail by way of embodiments thereof illustrated in the accompanying drawings.

### First Embodiment

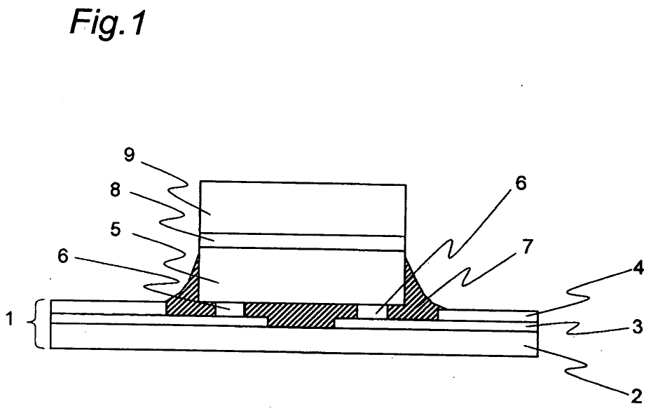

FIG. 1 shows a schematic sectional view of a COF semiconductor device with a heat spreader according to a first embodiment of the invention.

The COF semiconductor device with the heat spreader includes a flexible tape board 1 as an example of the tape board, a semiconductor element 5 mounted on the flexible tape board 1, and a heat spreader 9 mounted on the semiconductor element 5.

The flexible tape board 1 has a base film 2, interconnection lines 3 formed on the base film 2, and resist 4 formed on the interconnection lines 3. The resist 4 is so formed as not to cover part of the interconnection lines 3. It is noted that the interconnection lines 3 are an example of the interconnection pattern.

Bump electrodes 6 made of, for example, gold are formed on a front face of the semiconductor element 5. On the other hand, a heat spreader 9 is bonded via a die bond sheet 8 to the rear face of the semiconductor element 5 (a surface of the semiconductor element opposite to its surface on which the bump electrodes 6 are formed). An underfill resin 7 is filled between the flexible tape board 1 and the semiconductor element 5.

A surface area of the heat spreader 9 on the semiconductor element 5 side is approximately equal to the surface area of the semiconductor element 5 on the heat spreader 9 side. That is, the area of a surface of the heat spreader 9 to be bonded to the semiconductor element 5 is approximately equal to the area of the rear face of the semiconductor element 5.

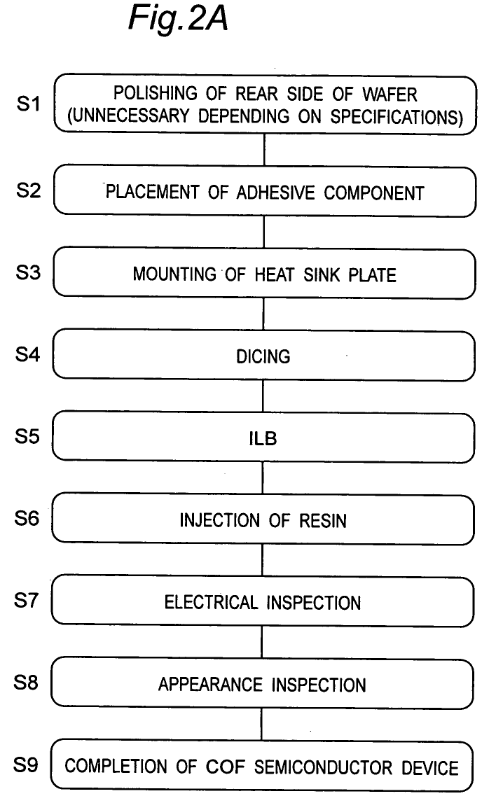

FIG. 2A shows an assembly flowchart of the COF semiconductor device with the heat spreader. Also, FIGS. 2B to 2D show an assembly process views of the COF semiconductor device with the heat spreader.

In an assembly method for the COF semiconductor device with the heat spreader, first, desired circuits and bump electrodes 6 are formed on a surface of a wafer and thereafter the rear side of the wafer is polished, by which a wafer 10 shown in FIG. 2B is obtained (step S1). The resulting wafer 10 makes the material of the semiconductor element 5. This means that the wafer 10 includes a plurality of semiconductor elements 5.

Next, a die bond sheet 8 generally equal in size to the wafer 10 is bonded to the rear side of the wafer 10 (step S2). Instead of the bonding of the die bond sheet 8 to the rear side of the wafer 10, heat-sink silicon resin may be applied to the rear side of the wafer 10.

Next, a heat-sink metal plate 11, which is a material of the heat spreader 9, is bonded to the rear side of the wafer 10 via the die bond sheet 8 (step S3). The size of the heat-sink metal plate 11 is generally equal to the wafer size. That is, the surface area of the heat-sink metal plate 11 on the wafer 10 side is generally equal to the surface area of the wafer 10. In other words, an opposing area of the heat-sink metal plate 11 to the wafer 10 is generally equal to an opposing area of the wafer 10 to the heat-sink metal plate 11. It is noted that the heat-sink metal plate 11 is an example of the heat sink plate.

Next, as shown in FIG. 2C, the wafer 10 together with the heat-sink metal plate 11 is cut by a dicing blade 12, by which a plurality of semiconductor elements 5 with the bump electrodes 6 and the heat spreader 9 provided thereon are formed as shown in FIG. 2D (step S4). In this process, the semiconductor element 5 and the heat spreader 9 are generally equal sized (in projected area). That is, area of the rear face of the semiconductor element 5 and the area of the surface of the heat spreader 9 on the semiconductor element 5 side are generally equal to each other.

Next, the semiconductor element 5 is bonded to the flexible tape board 1 (step S5). More specifically, the bump electrodes 6 of the semiconductor element 5 are connected to the interconnection lines 3 exposed in the flexible tape board 1. In this case, the interconnection lines 3 that are not connected to the bump electrodes 6 are covered with the resist 4.

Next, the underfill resin 7 as a protective material is filled between the semiconductor element 5 and the flexible tape board 1 and thereafter subjected to curing, by which the underfill resin 7 is cured (step S6).

Finally, an electrical inspection and an appearance inspection are performed, where the COF semiconductor device with the heat spreader is completed (steps S7-S9).

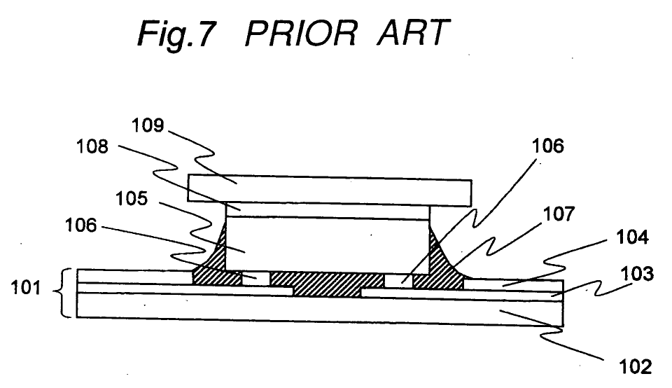

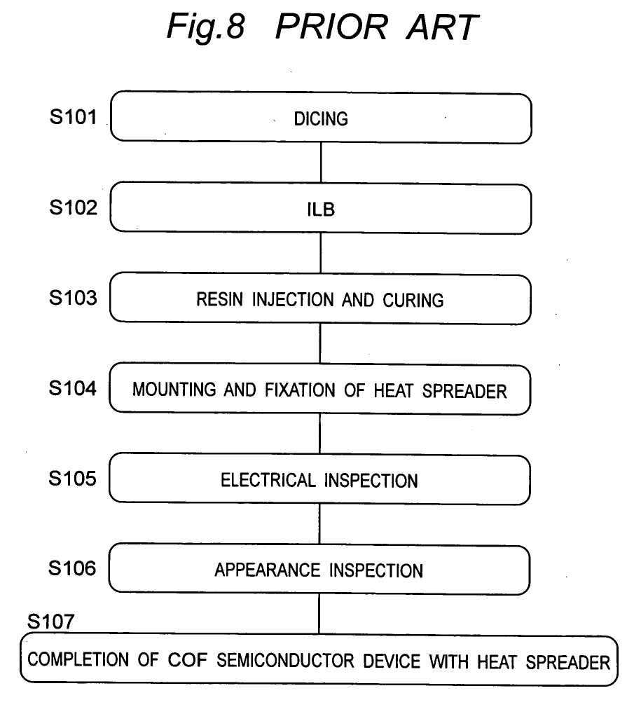

As shown above, the semiconductor element 5 with the bump electrodes 6 and the heat spreader 9 provided thereon can be obtained by cutting the wafer 10 together with the heat-sink metal plate 11 by the dicing blade 12. Accordingly, there is no step for bonding the chip-like heat spreader to the chip-like semiconductor element as would be involved in the prior art example of FIGS. 7 and 8. Thus, the manufacturing process for the COF semiconductor device with the heat spreader can be simplified so that the manufacturing cost can be reduced and besides its reliability can be enhanced.

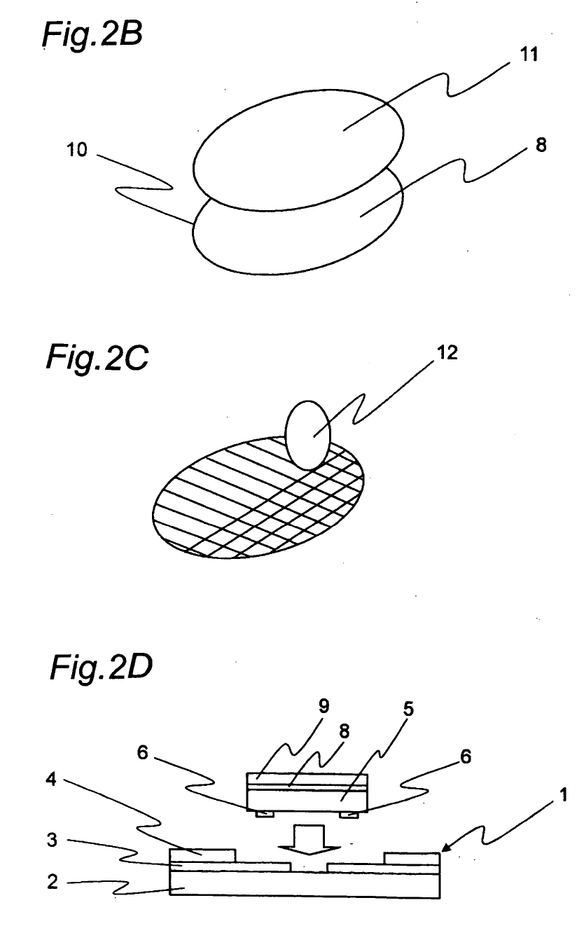

Also, the thickness of the semiconductor element 5 may be freely changed by rear side polishing of the wafer according to limitations on the height in applications, specifications of contraction with the users, the price and thermal conductivity of the heat spreader and the like. Moreover, the thickness of the heat spreader 9 may be freely changed by a change of the thickness of the heat-sink metal plate 11. That is, according to the manufacturing method of this first embodiment, a heat spreader-equipped COF semiconductor device lower in height than the heat spreader-equipped COF semiconductor device of FIG. 1 as shown in FIG. 3 can easily be formed.

In this first embodiment, after the semiconductor element 5 is made in the wafer 10, the die bond sheet 8 is bonded to the rear side of the wafer 10. Instead, the semiconductor element 5 may be made in the wafer 10 after the die bond sheet 8 is bonded to the rear side of the wafer 10. Needless to say, in the case where the semiconductor element 5 is made in the wafer 10 after the bonding of the die bond sheet 8 to the rear side of the wafer 10, the bump electrodes 6 are formed in the surface of the wafer 10 after the making of the semiconductor element 5 in the wafer 10.

### Second Embodiment

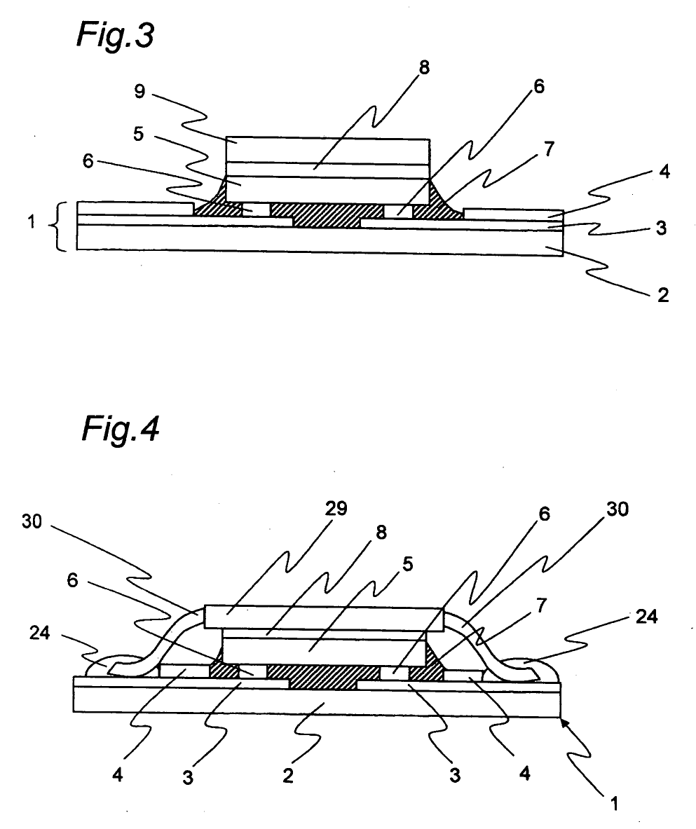

FIG. 4 shows a schematic sectional view of a COF semiconductor device with a heat spreader according to a second embodiment of the invention.

The COF semiconductor device with the heat spreader includes a flexible tape board 1 as an example of the tape board, a semiconductor element 5 mounted on the flexible tape board 1, and a heat spreader 29 mounted on the semiconductor element 5. This heat spreader 29 functions as the heat spreader.

The flexible tape board 1 has a base film 2, interconnection lines 3 formed on the base film 2, and resist 4 formed on the interconnection lines 3. The resist 4 is so formed as not to cover part of the interconnection lines 3. It is noted that the interconnection lines 3 are an example of the interconnection pattern.

Bump electrodes 6 made of, for example, gold are formed on a front face of the semiconductor element 5. On the other hand, a heat spreader 29 is bonded via a die bond sheet 8 to the rear face of the semiconductor element 5 (a surface of the semiconductor element opposite to its surface on which the bump electrodes 6 are formed). Further, an underfill resin 7 is filled between the flexible tape board 1 and the semiconductor element 5.

The heat spreader 29 is larger than the semiconductor element 5. More specifically, a surface area of the heat spreader 29 on the semiconductor element 5 side is larger than the surface area of the semiconductor element 5 on the heat spreader 29 side. That is, the area of a surface of the heat spreader 29 to be bonded to the semiconductor element 5 is approximately larger than the area of the rear face of the semiconductor element 5. Also, peripheral portion of the heat spreader 29 is electrically connected via connecting portions 30 to the interconnection lines 3 by means of solder 24. The connecting portions 30 are an example of the lead portion.

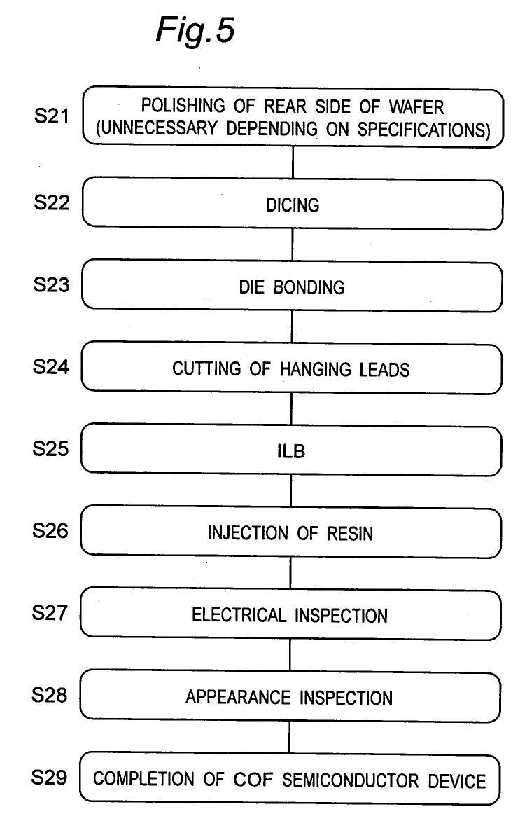

FIG. 5 shows an assembly flowchart of the COF semiconductor device with the heat spreader.

In an assembly method for the COF semiconductor device with the heat spreader, first, desired circuits and bump electrodes 6 are formed on a surface of a wafer and thereafter the rear side of the wafer is polished, by which a wafer with the bump electrodes 6 provided thereon is obtained (step S21). The resulting wafer makes the material of the semiconductor element 5. This means that the wafer 10 includes a plurality of semiconductor elements 5.

Next, the wafer is cut by a dicing blade, by which a plurality of semiconductor elements 5 with the bump electrodes 6 provided thereon are formed (step S22).

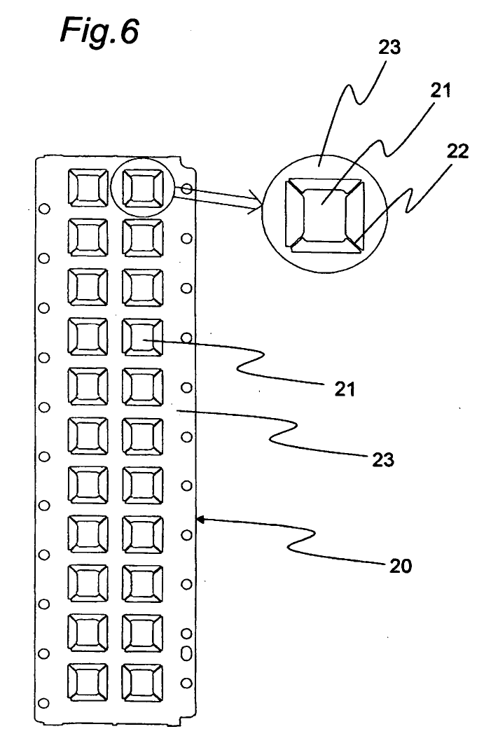

Next, the semiconductor element 5 is die-bonded to a die pad portion 21 of a lead frame 20 shown in FIG. 6 with a die bond paste (step S23). The die pad portion 21 is held to a frame portion 23 by hanging leads 22. Also, the surface area of the die pad portion 21 on the semiconductor element 5 side is set larger than the surface area of the semiconductor element 5 on the die pad portion 21 side.

Next, end portions of the hanging leads 22 on the frame portion 23 side are cut, by which the die pad portion 21 and the hanging leads 22 are separated from the frame portion 23 (step S24). As a result of this, a semiconductor element 5 with the bump electrodes 6, the heat spreader 29 and the connecting portions 30 provided thereon can be obtained. The heat spreader 29 is implemented by the die pad portion 21, and the connecting portions 30 are implemented by the hanging leads 22.

Next, the semiconductor element 5 is bonded to the flexible tape board 1 (step S25). More specifically, the bump electrodes 6 of the semiconductor element 5 are connected to exposed portions of the interconnection lines 3 and besides the connecting portions 30 adjoining the heat spreader 29 are electrically connected to the other exposed portions of the interconnection lines 3.

Next, the underfill resin 7 as a protective material is filled between the semiconductor element 5 and the flexible tape board 1 and thereafter subjected to curing, by which the underfill resin 7 is cured (step S26).

Finally, an electrical inspection and an appearance inspection are performed, where the COF semiconductor device with the heat spreader is completed (steps S27-S29).

As shown above, the semiconductor element 5 with the bump electrodes 6 and the heat spreader 29 provided thereon can be obtained by performing the steps S21 to S23, which are the same as those for conventional mold packages, and by thereafter cutting end portions of the hanging leads 22 to the frame portion 23 side. Accordingly, there is no step for bonding the chip-like heat spreader to the chip-like semiconductor element as would be involved in the prior art example of FIGS. 7 and 8. Thus, the manufacturing process for the COF semiconductor device with the heat spreader can be simplified so that the manufacturing cost can be reduced and besides its reliability can be enhanced.

Further, by the heat spreader 29 being electrically connected to the interconnection lines 3 via the connecting portions 30, the electric potential of the rear face of the semiconductor element 5 can be connected via the interconnection lines 3 to the external. Thus, electrical characteristics of the semiconductor element 5 such as anti-noise characteristics can be improved.

It is noted that the lead frame 20 is a lead frame which is used in conventional mold packages.

In the second embodiment, the surface area of the heat spreader 29 on the semiconductor element 5 side is set larger than the surface area of the semiconductor element 5 on the heat spreader 29 side. However, the surface area of the heat spreader 29 on the semiconductor element 5 side may be set generally equal to the surface area of the semiconductor element 5 on the heat spreader 29 side.

Although the present invention has been described as above, it is obvious that the present invention can be modified by a variety of methods. Such modifications are not regarded as departing from the spirit and scope of the present invention, and it is appreciated that improvements apparent to those skilled in the art are fully included within the scope of the following claims.

1. A semiconductor device comprising:
a semiconductor element; and a heat spreader mounted on the semiconductor element, wherein
an area of a surface of the heat spreader on one side closer to the semiconductor element is generally equal to an area of a surface of the semiconductor element on one side closer to the heat spreader.

2. The semiconductor device as claimed in claim 1, wherein
the semiconductor element and the heat spreader are changeable in thickness independently of each other.

3. The semiconductor device as claimed in claim 1, wherein
the heat spreader is made of metal.

4. The semiconductor device as claimed in claim 1, wherein
the heat spreader is bonded to the semiconductor element with a die bond sheet.

5. The semiconductor device as claimed in claim 1, wherein
the heat spreader is bonded to the semiconductor element with a heat-sinking silicon resin.

6. The semiconductor device as claimed in claim 1, wherein
the heat spreader is a die pad portion of a lead frame.

7. A method for manufacturing a semiconductor device comprising the steps of:
bonding a heat sink plate to a wafer; and
subjecting the wafer together with the heat sink plate to dicing to form a semiconductor element formed of part of the wafer and to form a heat spreader formed of part of the heat sink plate.

8. A semiconductor device comprising:
a tape board having an interconnection pattern; a semiconductor element which is mounted on the tape board so that one face of the semiconductor element faces the tape board; and a heat spreader mounted on the other face of the semiconductor element, wherein
the heat spreader is a die pad portion of a lead frame.

9. The semiconductor device as claimed in claim 8, wherein
the heat spreader is electrically connected to the interconnection pattern via a lead portion.

10. A method for manufacturing a semiconductor device comprising the steps of:
die-bonding a semiconductor element to a die pad portion of a lead frame, the lead frame having the die pad portion and a frame portion surrounding the die pad portion with one face of the semiconductor element opposed to the die pad portion;
separating the die pad portion together with the semiconductor element from the frame portion; and
mounting the semiconductor element onto the tape board with the other face of the semiconductor element opposed to the tape board.
